(19) United States
(12) Patent Application Publication
(10) Pub. No.: US 2019/0114951 A1
(43) Pub. Date: Apr. 18, 2019

(54) GATE DRIVING CIRCUITS AND DISPLAY APPARATUSES

(71) Applicants: BOE Technology Group Co., Ltd., Beijing (CN); Beijing BOE Display Technology Co., Ltd., Beijing (CN)

(72) Inventors: Feng Li, Beijing (CN); Yu Ma, Beijing (CN); Yan Yan, Beijing (CN); Qi Sang, Beijing (CN)

(21) Appl. No.: 15/910,117

(22) Filed: Mar. 2, 2018

(30) Foreign Application Priority Data
Oct. 13, 2017 (CN) 201710952257.0

(51) Int. Cl. G09G 3/20; G11C 19/28

(52) U.S. Cl. CPC G09G 3/20; G09G 2310/0286; G09G 2320/0257; G11C 19/28

(57) ABSTRACT

The present disclosure provides a gate driving circuit and a display apparatus. The gate driving circuit comprises a plurality of cascaded shift registers, wherein the shift registers each comprise an input sub-circuit, an output sub-circuit, an output de-noising sub-circuit, a capacitor sub-circuit and a reset sub-circuit, wherein the output de-noising sub-circuit is electrically connected to a first reference voltage signal terminal, a second reference voltage signal terminal and an output signal terminal, and for each stage of shift register except for a first stage of shift register, the second reference voltage signal terminal is electrically connected to an input signal terminal of a stage of shift register immediately prior to the current stage of shift register.

### CROSS-REFERENCE TO RELATED APPLICATION(S)

This application claims priority to the Chinese Patent Application No. 201710952257.0, filed on Oct. 13, 2017, which is incorporated herein by reference in its entirety.

### TECHNICAL FIELD

The present disclosure relates to the field of display technology, and more particularly, to a gate driving circuit and a display apparatus.

### BACKGROUND

A typical gate driving circuit is composed of a plurality of cascaded shift registers. A driving output signal terminal of each stage of shift register is connected to a corresponding gate line. A scanning signal is sequentially input to various rows of gate lines on a display panel through respective stages of shift registers. In the shift registers, signals output by output terminals thereof are easily affected, and therefore it is difficult to ensure the stability.

### SUMMARY

According to a first aspect of the present disclosure, there is provided a gate driving circuit comprising a plurality of cascaded shift registers, wherein the shift registers each comprise an input sub-circuit, an output sub-circuit, an output de-noising sub-circuit, a capacitor sub-circuit and a reset sub-circuit, wherein the output de-noising sub-circuit is electrically connected to a first reference voltage signal terminal, a second reference voltage signal terminal and an output signal terminal, and for each stage of shift register except for a first stage of shift register, the second reference voltage signal terminal is electrically connected to an input signal terminal of a stage of shift register immediately prior to the current stage of shift register.

In an embodiment, the input sub-circuit is electrically connected to the input signal terminal and a first node and is configured to provide an input signal from the input signal terminal to the first node; the output sub-circuit is electrically connected to the first node, a clock signal terminal and the output signal terminal and is configured to provide a clock signal from the clock signal terminal to the output signal terminal under the control of a potential at the first node; the capacitor sub-circuit is electrically connected to the first node and the output signal terminal; the reset sub-circuit is electrically connected to a reset signal terminal, the first node and the first reference voltage signal terminal and is configured to provide a first reference voltage signal from the first reference voltage signal terminal to the first node under the control of a reset signal from the reset signal terminal; the output de-noising sub-circuit is configured to provide the first reference voltage signal from the first reference voltage signal terminal to the output signal terminal under the control of a second reference voltage signal from the second reference voltage signal terminal.

In an embodiment, the input sub-circuit comprises a first switch transistor, wherein the first switch transistor has a gate and a first electrode both electrically connected to the input signal terminal, and a second electrode electrically connected to the first node.

In an embodiment, the output sub-circuit comprises a second switch transistor, wherein the second switch transistor has a gate electrically connected to the first node, a first electrode electrically connected to the clock signal terminal, and a second electrode electrically connected to the output signal terminal.

In an embodiment, the output de-noising sub-circuit comprises a third switch transistor, wherein the third switch transistor has a gate electrically connected to the second reference voltage signal terminal, a first electrode electrically connected to the first reference voltage signal terminal, and a second electrode electrically connected to the output signal terminal.

In an embodiment, the capacitor sub-circuit comprises a first capacitor, wherein the first capacitor has a first terminal electrically connected to the first node and a second terminal electrically connected to the output signal terminal.

In an embodiment, the reset sub-circuit comprises a fourth switch transistor, wherein the fourth switch transistor has a gate electrically connected to the reset signal terminal, a first electrode electrically connected to the first reference voltage signal terminal, and a second electrode electrically connected to the first node.

In an embodiment, the shift registers each further comprise a node de-noising sub-circuit, wherein the node de-noising sub-circuit is electrically connected to a frame start signal terminal, the first node and the first reference voltage signal terminal, and is configured to provide the first reference voltage signal from the first reference voltage signal terminal to the first node under the control of a signal from the frame start signal terminal.

In an embodiment, the node de-noising sub-circuit comprises a fifth switch transistor, wherein the fifth switch transistor has a gate electrically connected to the frame start signal terminal, a first electrode electrically connected to the first reference voltage signal terminal, and a second electrode electrically connected to the first node.

In an embodiment, the shift registers each further comprise a pull-down control sub-circuit and a pull-down sub-circuit, wherein the pull-down control sub-circuit is electrically connected to the first reference voltage signal terminal, a third reference voltage signal terminal, the first node, a second node and the input signal terminal, and is configured to provide the first reference voltage signal from the first reference voltage signal terminal to the second node under the control of the input signal from the input signal terminal or the potential at the first node or provide a third reference voltage signal from the third reference voltage signal terminal to the second node; and the pull-down sub-circuit is electrically connected to the first node, the second node, the first reference voltage signal terminal, and the output signal terminal and is configured to provide the first reference voltage signal from the first reference voltage signal terminal to the first node or the output signal terminal under the control of a potential at the second node.

In an embodiment, the pull-down control sub-circuit comprises a seventh switch transistor, an eighth switch transistor, and a ninth switch transistor, wherein the seventh switch transistor has a gate and a first electrode both electrically connected to the third reference voltage signal terminal, and a second electrode electrically connected to the second node; the eighth switch transistor has a gate electrically connected to the first node, a first electrode electrically connected to the first reference voltage signal terminal, and a second electrode electrically connected to the second node; and the ninth switch transistor has a gate electrically connected to the input signal terminal, a first electrode electrically connected to the first reference voltage signal terminal, and a second electrode electrically connected to the second node.

In an embodiment, the pull-down sub-circuit comprises a tenth switch transistor and a sixth switch transistor, wherein the tenth switch transistor has a gate electrically connected to the second node, a first electrode electrically connected to the first reference voltage signal terminal and a second electrode electrically connected to the first node; and the sixth switch transistor has a gate electrically connected to the second node, a first electrode electrically connected to the first reference voltage signal terminal and a second electrode electrically connected to the output signal terminal.

According to a second aspect of the present disclosure, there is provided a display apparatus, comprising the gate driving circuit which is described in any of the above embodiments.

### BRIEF DESCRIPTION OF THE DRAWINGS

FIG. 1 is a structural diagram of a shift register;

FIG. 2 is a structural diagram of a shift register according to an embodiment of the present disclosure;

FIG. 3 is a specific structural diagram of the shift register in FIG. 2;

FIG. 4 is a structural diagram of a shift register according to another embodiment of the present disclosure;

FIG. 5 is a specific structural diagram of the shift register in FIG. 4;

FIG. 6 is a timing diagram corresponding to the shift register in FIG. 3; and

FIG. 7 is a structural diagram of a gate driving circuit according to an embodiment of the present disclosure.

### DETAILED DESCRIPTION

In order to make the purposes, technical solutions, and advantages of the present disclosure more clear, specific implementations of the gate driving circuit and the display apparatus according to the embodiments of the present disclosure will be described in detail below with reference to the accompanying drawings. It should be understood that preferred embodiments described below are merely used for describing and explaining the present disclosure, but not for limiting the present disclosure. Further, the embodiments in the present application and the features in the embodiments can be combined with each other without a conflict.

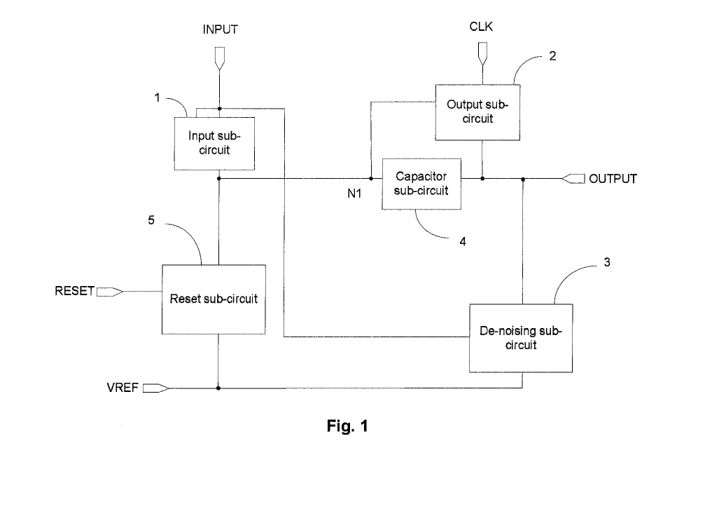

FIG. 1 illustrates a structural diagram of a shift register. In the shift register of FIG. 1, a signal output by an output signal terminal OUTPUT is easily affected by a first node N1 due to a strong coupling effect of a capacitor sub-circuit 4. Therefore, a de-noising sub-circuit 3 is provided to de-noise the output signal terminal OUTPUT so as to ensure the stability of the signal output by the output signal terminal OUTPUT.

However, the de-noising sub-circuit 3 in FIG. 1 is configured to de-noise the output signal terminal OUTPUT under the control of an input signal terminal INPUT. Due to the presence of a rising edge of a signal from the input signal terminal INPUT, when a potential at the first node N1 increases, the signal input to the input signal terminal INPUT has not increased to the highest level, which results in a weak de-noising capability of the de-noising sub-circuit 3 relative to the output signal terminal OUTPUT, thus affecting the stability of the output signal.

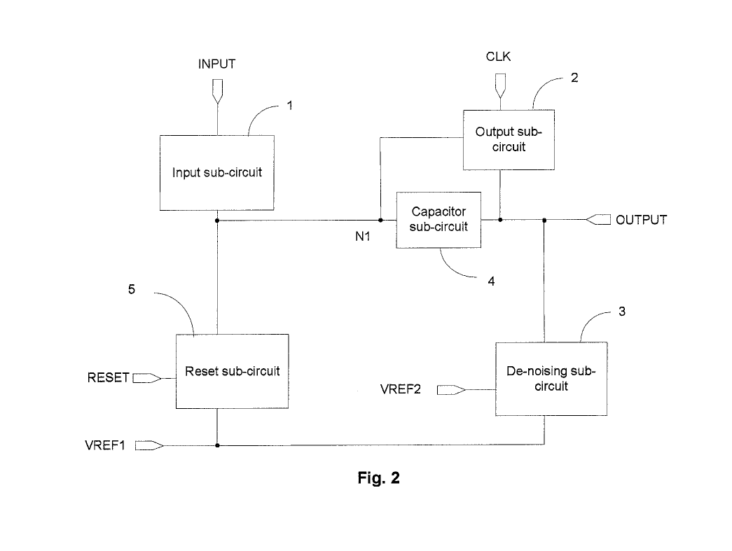

FIG. 2 illustrates a gate driving circuit according to an embodiment of the present disclosure. The gate driving circuit in FIG. 2 comprises a plurality of cascaded shift registers. The shift registers each comprise an input sub-circuit 1, an output sub-circuit 2, an output de-noising sub-circuit 3, a capacitor sub-circuit 4 and a reset sub-circuit 5. The output de-noising sub-circuit 3 is electrically connected to a second reference voltage signal terminal VREF2, a first reference voltage signal terminal VREF1 and an output signal terminal OUTPUT respectively. For each stage of shift register except for a first stage of shift register, the second reference voltage signal terminal VREF2 is electrically connected to an input signal terminal INPUT of a stage of shift register immediately prior to the current stage of shift register.

According to the above gate driving circuit, the output de-noising sub-circuit is electrically connected to the second reference voltage signal terminal to de-noise the output signal terminal of the current stage of shift register under the control of a signal of the input signal terminal of the immediately previous stage of shift register. As the signal of the input signal terminal of the immediately previous stage of shift register is ahead of a signal of the input signal terminal of the current stage of shift register by a time required to scan a row of pixels, the output signal terminal of the current stage of shift register is de-noised by the signal of the input signal terminal of the immediately previous stage of shift register, which can better ensure the stability of the signal output by the output signal terminal.

It should be illustrated that the second reference voltage signal terminal of the current stage of shift register is electrically connected to the input signal terminal of the immediately previous stage of shift register, so that a voltage signal of the second reference voltage signal terminal may be ahead of the signal of the input signal terminal of the current stage of shift register, so as to avoid a situation in which due to the presence of a rising edge of the signal of the input signal terminal of the current stage of shift register, it takes a certain amount of time for the signal to reach the highest potential to control the output de-noising sub-circuit to de-noise the output signal terminal, and thus due to the time delay, it results in a weak de-noising capability relative to the output signal, thereby affecting the stability of the signal output.

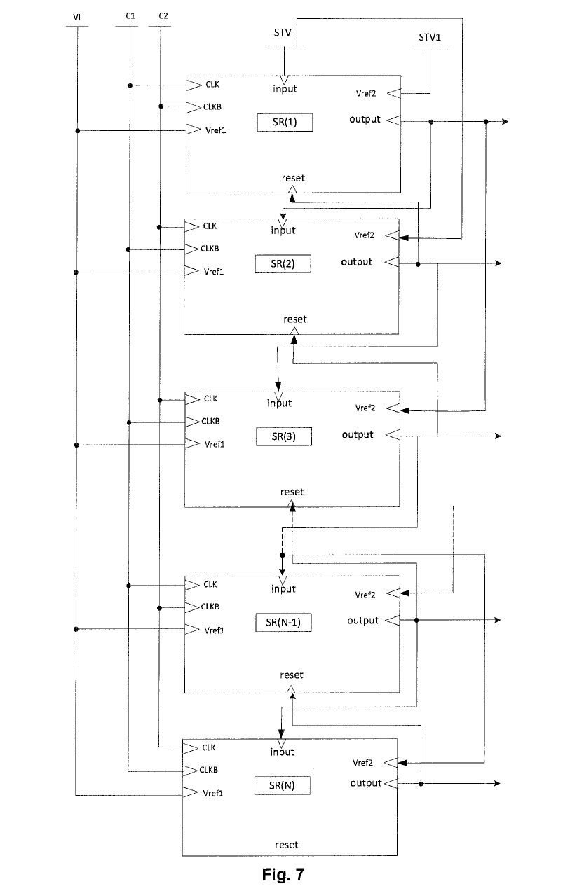

Specifically, in the gate driving circuit according to the embodiment of the present disclosure, as shown in FIG. 7, the second reference voltage signal terminal VREF2 of the current stage of shift register is electrically connected to the input signal terminal INPUT of the immediately previous stage of shift register so that there is no need to provide an additional wiring to provide a signal to the second reference voltage signal terminal VREF2, which saves the space and reduces the production cost.

It should be illustrated that, in the gate driving circuit according to the embodiment of the present disclosure, as shown in FIG. 7, a second reference voltage signal terminal VREF2 of the first stage of shift register may be electrically connected to an additional new voltage signal terminal, as long as it is ensured that a second reference voltage signal from the second reference voltage signal terminal VREF2 of the first stage of shift register is ahead of a signal of an input signal terminal INPUT of the first stage of shift register by a time required to scan a row of pixels, which is not specifically limited here.

Specifically, in the gate driving circuit according to the embodiment of the present disclosure, as shown in FIG. 2, the input sub-circuit 1 is electrically connected to an input signal terminal INPUT and a first node N1 and is configured to provide a signal of the input signal terminal INPUT to the first node N1 under the control of the input signal terminal INPUT;

the output sub-circuit 2 is electrically connected to the first node N1, a clock signal terminal CLK and the output signal terminal OUTPUT and is configured to provide a clock signal from the clock signal terminal CLK to the output signal terminal OUTPUT under the control of a potential at the first node N1;

the capacitor sub-circuit 4 is electrically connected to the first node N1 and the output signal terminal OUTPUT. In an embodiment, the capacitor sub-circuit 4 is configured to maintain the stability of voltages at the first node N1 and the output signal terminal OUTPUT;

the output de-noising sub-circuit 3 is configured to provide a first reference voltage signal V1 from the first reference voltage signal terminal VREF1 to the output signal terminal OUTPUT under the control of the second reference voltage signal terminal VREF2, wherein the second reference voltage signal terminal VREF2 of the current stage of shift register is electrically connected to the input signal terminal INPUT of the immediately previous stage of shift register; and

the reset sub-circuit 5 is electrically connected to a reset signal terminal RESET, the first node N1 and the first reference voltage signal terminal VREF1 and is configured to provide the signal of the first reference voltage signal terminal VREF1 to the first node N1 under the control of the reset signal terminal RESET.

The present disclosure will be described in detail below with reference to specific embodiments. It should be illustrated that the present embodiment is intended to better explain the present disclosure, but not to limit the present disclosure.

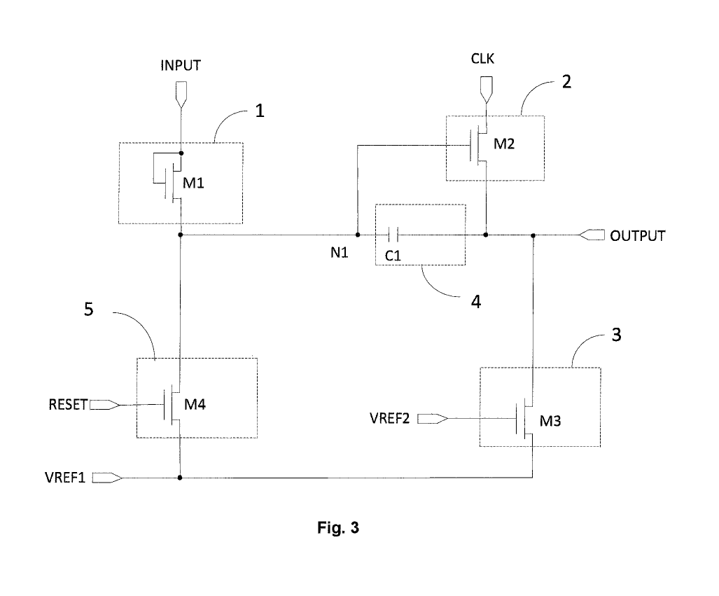

In a specific implementation, in the gate driving circuit according to the embodiment of the present disclosure, as shown in FIG. 3, the input sub-circuit 1 comprises a first switch transistor M1, wherein

the first switch transistor M1 has a gate and a first electrode both electrically connected to the input signal terminal INPUT, and a second electrode electrically connected to the first node N1.

A specific structure of the input sub-circuit in the shift register is merely described by way of example. In a specific implementation, the specific structure of the input sub-circuit is not limited to the above structure according to the embodiment of the present disclosure, and may also be other structures known by those skilled in the art, which is not limited here.

In a specific implementation, in the gate driving circuit according to the embodiment of the present disclosure, as shown in FIG. 3, the output sub-circuit 2 comprises a second switch transistor M2, wherein

the second switch transistor M2 has a gate electrically connected to the first node N1, a first electrode electrically connected to the clock signal terminal CLK, and a second electrode electrically connected to the output signal terminal OUTPUT.

A specific structure of the output sub-circuit in the shift register is merely described by way of example. In a specific implementation, the specific structure of the output sub-circuit is not limited to the above structure according to the embodiment of the present disclosure, and may also be other structures known by those skilled in the art, which is not limited here.

In a specific implementation, in the gate driving circuit according to the embodiment of the present disclosure, as shown in FIG. 3, the output de-noising sub-circuit 3 comprises a third switch transistor M3, wherein

the third switch transistor M3 has a gate electrically connected to the second reference voltage signal terminal VREF2, a first electrode electrically connected to the first reference voltage signal terminal VREF1, and a second electrode electrically connected to the output signal terminal OUTPUT.

A specific structure of the output de-noising sub-circuit in the shift register is merely described by way of example. In a specific implementation, the specific structure of the output de-noising sub-circuit is not limited to the above structure according to the embodiment of the present disclosure, and may also be other structures known by those skilled in the art, which is not limited here.

In a specific implementation, in the gate driving circuit according to the embodiment of the present disclosure, as shown in FIG. 3, the capacitor sub-circuit 4 comprises a first capacitor C1, wherein

the first capacitor C1 has a first terminal electrically connected to the first node N1 and a second terminal electrically connected to the output signal terminal OUTPUT.

A specific structure of the capacitor sub-circuit in the shift register is merely described by way of example. In a specific implementation, the specific structure of the capacitor sub-circuit is not limited to the above structure according to the embodiment of the present disclosure, and may also be other structures known by those skilled in the art, which is not limited here.

In a specific implementation, in the gate driving circuit according to the embodiment of the present disclosure, as shown in FIG. 3, the reset sub-circuit 5 comprises a fourth switch transistor M4, wherein

the fourth switch transistor M4 has a gate electrically connected to the reset signal terminal RESET, a first electrode electrically connected to the first reference voltage signal terminal VREF1, and a second electrode electrically connected to the first node N1.

A specific structure of the reset sub-circuit in the shift register is merely described by way of example. In a specific implementation, the specific structure of the reset sub-circuit is not limited to the above structure according to the embodiment of the present disclosure, and may also be other structures known by those skilled in the art, which is not limited here.

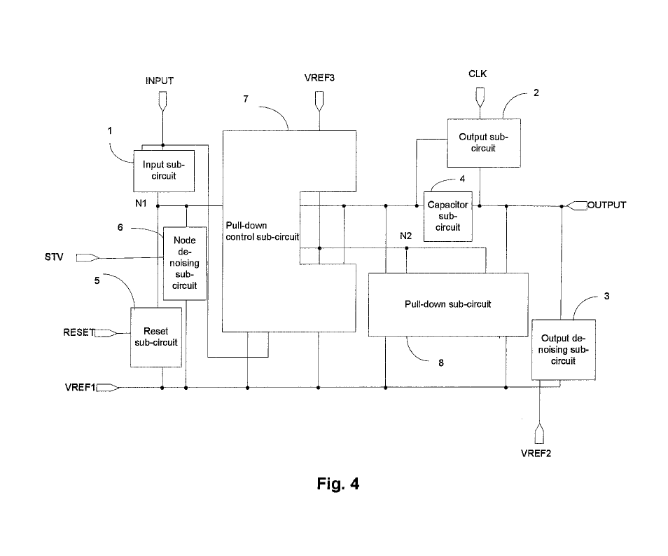

In a specific implementation, in the gate driving circuit according to the embodiment of the present disclosure, as shown in FIG. 4, the shift registers each further comprise a noise de-noising sub-circuit 6.

The node de-noising sub-circuit 6 is electrically connected to a frame start signal terminal STV, the first node N1 and the first reference voltage signal terminal VREF1, and is configured to provide the first reference voltage signal from the first reference voltage signal terminal VREF1 to the first node N1 under the control of the frame start signal terminal STV.

In a specific implementation, in the gate driving circuit according to the embodiment of the present disclosure, the node de-noising sub-circuit may be provided so that the first node may be de-noised before one frame starts to be scanned, thereby preventing a residual signal of a previous frame from having an impact on the scanning of the current frame.

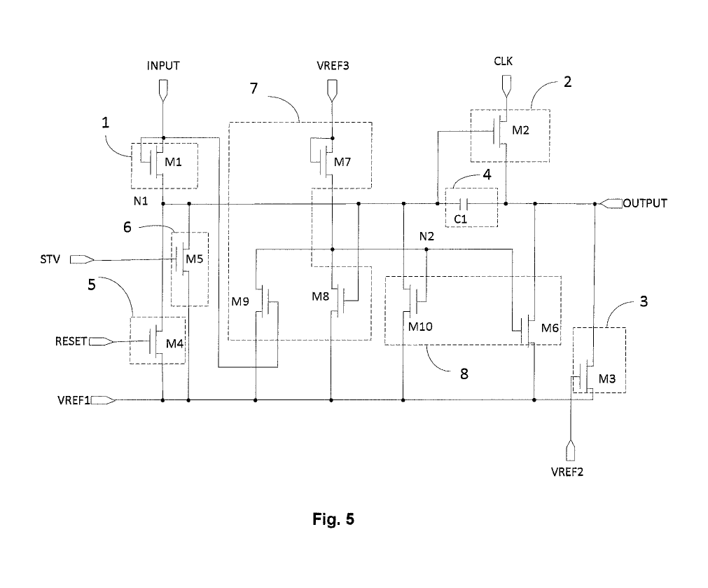

Specifically, in the gate driving circuit according to the embodiment of the present disclosure, as shown in FIG. 5, the node de-noising sub-circuit 6 comprises a fifth switch transistor M5, wherein the fifth switch transistor M5 has a gate electrically connected to the frame start signal terminal STV, a first electrode electrically connected to the first reference voltage signal terminal VREF1, and a second electrode electrically connected to the first node N1.

A specific structure of the node de-noising sub-circuit in the shift register is merely described by way of example. In a specific implementation, the specific structure of the node de-noising sub-circuit is not limited to the above structure according to the embodiment of the present disclosure, and may also be other structures known by those skilled in the art, which is not limited here.

In a specific implementation, in the gate driving circuit according to the embodiment of the present disclosure, as shown in FIG. 4, the shift registers each further comprise a pull-down control sub-circuit 7 and a pull-down sub-circuit 8.

The pull-down control sub-circuit 7 is electrically connected to the first reference voltage signal terminal VREF1, a third reference voltage signal terminal VREF3, the first node N1, a second node N2 and the input signal terminal INPUT, and is configured to provide the first reference voltage signal from the first reference voltage signal terminal VREF1 to the second node N2 under the control of the input signal terminal INPUT or the potential at the first node N1 or provide a third reference voltage signal from the third reference voltage signal terminal VREF3 to the second node N2 under the control of the third reference voltage signal terminal VREF3; and

the pull-down sub-circuit 8 is electrically connected to the first node N1, the second node N2, the first reference voltage signal terminal VREF1, and the output signal terminal OUTPUT and is configured to provide the first reference voltage signal from the first reference voltage signal terminal VREF1 to the first node N1 or the output signal terminal OUTPUT under the control of a potential at the second node N2.

Specifically, in the gate driving circuit according to the embodiment of the present disclosure, as shown in FIG. 5, the pull-down control sub-circuit 7 comprises a seventh switch transistor M7, an eighth switch transistor M8, and a ninth switch transistor M9, wherein

the seventh switch transistor M7 has a gate and a first electrode both electrically connected to the third reference voltage signal terminal VREF3, and a second electrode electrically connected to the second node N2;

the eighth switch transistor M8 has a gate electrically connected to the first node N1, a first electrode electrically connected to the first reference voltage signal terminal VREF1, and a second electrode electrically connected to the second node N2; and

the ninth switch transistor M9 has a gate electrically connected to the input signal terminal INPUT, a first electrode electrically connected to the first reference voltage signal terminal VREF1, and a second electrode electrically connected to the second node N2.

It should be illustrated that in the gate driving circuit according to the embodiment of the present disclosure, the seventh switch transistor provides the third reference voltage signal from the third reference voltage signal terminal to the second node under the control of the third reference voltage signal terminal; the eighth switch transistor provides the first reference voltage signal from the first reference voltage signal terminal to the second node under the control of the potential at the first node; and the ninth switch transistor provides the first reference voltage signal from the first reference voltage signal terminal to the second node under the control of the input signal terminal.

A specific structure of the pull-down control sub-circuit in the shift register is merely described by way of example. In a specific implementation, the specific structure of the pull-down control sub-circuit is not limited to the above structure according to the embodiment of the present disclosure, and may also be other structures known by those skilled in the art, which is not limited here.

Specifically, in the gate driving circuit according to the embodiment of the present disclosure, as shown in FIG. 5, the pull-down sub-circuit 8 comprises a tenth switch transistor M10 and a sixth switch transistor M6, wherein

the tenth switch transistor M10 has a gate electrically connected to the second node N2, a first electrode electrically connected to the first reference voltage signal terminal VREF1 and a second electrode electrically connected to the first node N1; and

the sixth switch transistor M6 has a gate electrically connected to the second node N2, a first electrode electrically connected to the first reference voltage signal terminal VREF1 and a second electrode electrically connected to the output signal terminal OUTPUT.

It should be illustrated that in the gate driving circuit according to the embodiment of the present disclosure, the tenth switch transistor provides the first reference voltage signal from the first reference voltage signal terminal to the first node under the control of the potential at the second node; and the sixth switch transistor provides the first reference voltage signal from the first reference voltage signal terminal to the output signal terminal under the control of the second node.

A specific structure of the pull-down sub-circuit in the shift register is merely described by way of example. In a specific implementation, the specific structure of the pull-down sub-circuit is not limited to the above structure according to the embodiment of the present disclosure, and may also be other structures known by those skilled in the art, which is not limited here.

In order to reduce the manufacturing process, in a specific implementation, in the gate driving circuit according to the embodiment of the present disclosure, all the switch transistors in each of the shift registers may be N-type switch transistors or all the switch transistors in each of the shift registers may also be P-type switch transistors, which is not limited here.

Further, in a specific implementation, in the shift register according to the embodiment of the present disclosure, each of the N-type switch transistors is turned on at a high potential signal and is turned off at a low potential signal; and each of the P-type switch transistors is turned off at a high potential signal, and is turned on at a low potential signal.

It should be illustrated that the switch transistors according to the embodiments of the present disclosure may be Thin Film Transistors (TFTs) or Metal Oxide Semiconductors (MOSs), which is not limited here. In a specific implementation, a control electrode of each of the switch transistors acts as a gate thereof, and a first electrode of the switch transistor may act as a source and a second electrode of the switch transistor may act as a drain, or the first electrode may act as a drain and the second electrode may act as a source depending on a type of the transistor and an input signal, which are not specifically distinguished here.

An operation process of the shift registers in the gate driving circuit according to the embodiments of the present disclosure will be described in detail below with reference to a circuit timing diagram. In the following description, a high potential signal is denoted as 1, and a low potential signal is denoted as 0, where 1 and 0 represent logic potentials only for better explaining the operation process of the shift registers according to the embodiments of the present disclosure, rather than potentials which are applied to a gate of each switch transistor in a specific implementation.

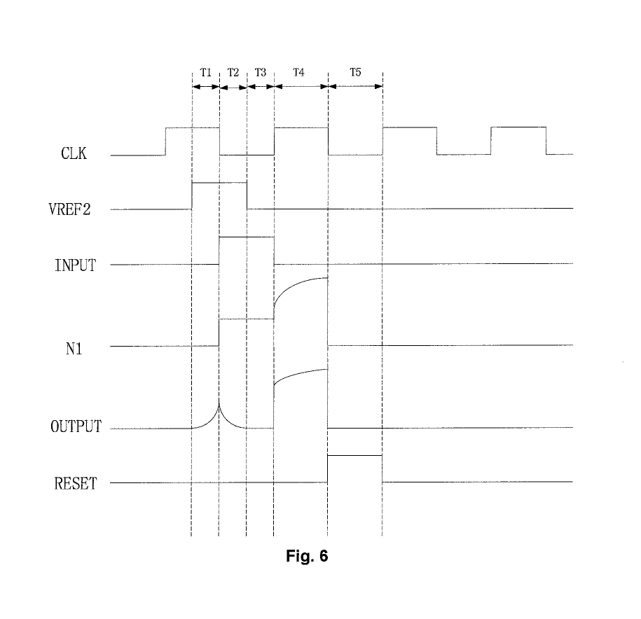

By taking the shift register shown in FIG. 3 as an example, all the transistors are N-type transistors; the signal of the first reference voltage signal terminal VREF1 is a low potential signal; and corresponding input and output timing diagrams are shown in FIG. 6. Specifically, five phases T1-T5 in the input and output timing diagrams shown in FIG. 6 are selected.

In the phase T1, INPUT=0, VREF2=1, CLK=1, and Reset=0.

As INPUT=0 and VREF2=1, when no signal is input to the input signal terminal INPUT, a signal is input to the second reference voltage signal terminal VREF2. The second reference voltage signal V2 from the second reference voltage signal terminal VREF2 is at a high level, and thus the third switch transistor M3 is turned on to provide the first reference voltage signal V1 from the first reference voltage signal terminal VREF1 to the output signal terminal OUTPUT, to de-noise the output signal terminal OUTPUT. Due to the presence of a rising edge of the second reference voltage signal V2, it takes a certain amount of time for the second reference voltage signal V2 to reach the highest voltage value, and thus a voltage of the output terminal OUTPUT temporarily increases, but at this time, no signal is input to the input signal terminal INPUT and there is no impact on the signal output by the output signal terminal OUTPUT.

In the phase T2, INPUT=1,VREF2=1, CLK=0 and Reset=0.

As VREF2=1, that is, the VREF2 is still maintained at a high level, the third switch transistor M3 is maintained in a turn-on state and continues to de-noise the output signal terminal OUTPUT. At this time, the second reference voltage signal V2 from the second reference voltage signal terminal VREF2 has reached the highest value, and thus the de-noising of the output signal terminal OUTPUT has been completed in this phase, so that the output signal terminal OUTPUT is maintained at a low level. At this time, the input signal terminal INPUT=1, to charge the first node N1, so that the first node N1 is maintained at a high level. At this time, although the second switch transistor M2 is turned on, CLK=0, and thus the output signal terminal OUTPUT is still maintained at a low level, and no signal is output.

In the phase T3, INPUT=1, VREF2=0, CLK=0, and Reset=0.

As the de-noising of the output signal terminal OUTPUT has been completed in the previous phase, VREF2=0 in this phase. At this time, INPUT=1, to still charge the first node N1, so that the first node N1 is maintained at a high potential. At this time, although the second switch transistor M2 is turned on, CLK=0, and thus the output signal terminal OUTPUT is still maintained at a low level and no signal is output.

In the phase T4, INPUT=0, VREF2=0, CLK=1, and Reset=0.

In this phase, INPUT=0, the first switch transistor M1 is turned off, but the first node N1 is still maintained at a high level as in the previous phase, and the second switch transistor M2 is turned on to provide the clock signal from the clock signal terminal CLK to the output signal terminal OUTPUT for outputting the signal. As the potential at the output signal terminal OUTPUT gradually changes from a low level to a high level, and due to a coupling effect of the first capacitor C1, the potential at the first node N1 gradually increases.

In the phase T5, INPUT=0, VREF2=0, CLK=0, and Reset=1.

As Reset=1, the fourth switch transistor M4 is turned on, to provide the first reference voltage signal V1 from the first reference voltage signal terminal VREF1 to the first node N1 to reset the first node N1.

Based on the same concept, the embodiments of the present disclosure further provide a display apparatus including any of the gate driving circuits according to the embodiments of the present disclosure. The display apparatus may be a display panel of any product having a display function, such as a mobile phone, a tablet computer, a television, a display, a notebook computer, a digital photo frame, a navigator etc. Implementations of the display apparatus can be known with reference to the embodiments of the gate driving circuit described above, and details thereof are not described again.

The embodiments of the present disclosure provide a gate driving circuit and a display apparatus. The gate driving circuit comprises a plurality of cascaded shift registers, wherein the shift registers each comprise an input sub-circuit, an output sub-circuit, an output de-noising sub-circuit, a capacitor sub-circuit and a reset sub-circuit, wherein the output de-noising sub-circuit is electrically connected to a first reference voltage signal terminal, a second reference voltage signal terminal and an output signal terminal, and for each stage of shift register except for a first stage of shift register, the second reference voltage signal terminal is electrically connected to an input signal terminal of a stage of shift register immediately prior to the current stage of shift register. The output de-noising sub-circuit is electrically connected to the second reference voltage signal terminal to de-noise the output signal terminal of the current stage of shift register under the control of a signal of the input signal terminal of the immediately previous stage of shift register. As the signal of the input signal terminal of the immediately previous stage of shift register is ahead of a signal of the input signal terminal of the current stage of shift register by a time required to scan a row of pixels, the output signal terminal of the current stage of shift register is de-noised by the signal of the input signal terminal of the immediately previous stage of shift register, which can better ensure the stability of the signal output by the output signal terminal.

Obviously, those skilled in the art can make various modifications and variations to the present disclosure without departing from the spirit and scope of the present disclosure. In this way, if these modifications and variations of the present disclosure fall within the scope of the claims of the present disclosure and the equivalent technologies thereof, the present disclosure is also intended to include these modifications and variations.

I/we claim:

1. A gate driving circuit comprising a plurality of cascaded shift registers, wherein the shift registers each comprise an input sub-circuit, an output sub-circuit, an output de-noising sub-circuit, a capacitor sub-circuit and a reset sub-circuit, wherein
the output de-noising sub-circuit is electrically connected to a first reference voltage signal terminal, a second reference voltage signal terminal and an output signal terminal, and
for each stage of shift register except for a first stage of shift register, the second reference voltage signal terminal is electrically connected to an input signal terminal of a stage of shift register immediately prior to the current stage of shift register.

2. The gate driving circuit according to claim 1, wherein
the input sub-circuit is electrically connected to the input signal terminal and a first node and is configured to provide an input signal from the input signal terminal to the first node;
the output sub-circuit is electrically connected to the first node, a clock signal terminal and the output signal terminal and is configured to provide a clock signal from the clock signal terminal to the output signal terminal under the control of a potential at the first node;
the capacitor sub-circuit is electrically connected to the first node and the output signal terminal;
the reset sub-circuit is electrically connected to a reset signal terminal, the first node and the first reference voltage signal terminal and is configured to provide a first reference voltage signal from the first reference voltage signal terminal to the first node under the control of a reset signal from the reset signal terminal;
the output de-noising sub-circuit is configured to provide the first reference voltage signal from the first reference voltage signal terminal to the output signal terminal under the control of a second reference voltage signal from the second reference voltage signal terminal.

3. The gate driving circuit according to claim 2, wherein the input sub-circuit comprises a first switch transistor, wherein
the first switch transistor has a gate and a first electrode both electrically connected to the input signal terminal, and a second electrode electrically connected to the first node.

4. The gate driving circuit according to claim 2, wherein the output sub-circuit comprises a second switch transistor, wherein
the second switch transistor has a gate electrically connected to the first node, a first electrode electrically connected to the clock signal terminal, and a second electrode electrically connected to the output signal terminal.

5. The gate driving circuit according to claim 2, wherein the output de-noising sub-circuit comprises a third switch transistor, wherein
the third switch transistor has a gate electrically connected to the second reference voltage signal terminal, a first electrode electrically connected to the first reference voltage signal terminal, and a second electrode electrically connected to the output signal terminal.

6. The gate driving circuit according to claim 2, wherein the capacitor sub-circuit comprises a first capacitor, wherein
the first capacitor has a first terminal electrically connected to the first node and a second terminal electrically connected to the output signal terminal.

7. The gate driving circuit according to claim 2, wherein the reset sub-circuit comprises a fourth switch transistor, wherein
the fourth switch transistor has a gate electrically connected to the reset signal terminal, a first electrode electrically connected to the first reference voltage signal terminal, and a second electrode electrically connected to the first node.

8. The gate driving circuit according to claim 2, wherein the shift registers each further comprise a node de-noising sub-circuit, wherein
the node de-noising sub-circuit is electrically connected to a frame start signal terminal, the first node and the first reference voltage signal terminal, and is configured to provide the first reference voltage signal from the first reference voltage signal terminal to the first node under the control of a signal from the frame start signal terminal.

9. The gate driving circuit according to claim 8, wherein the node de-noising sub-circuit comprises a fifth switch transistor, wherein
the fifth switch transistor has a gate electrically connected to the frame start signal terminal, a first electrode electrically connected to the first reference voltage signal terminal, and a second electrode electrically connected to the first node.

10. The gate driving circuit according to claim 2, wherein the shift registers each further comprise a pull-down control sub-circuit and a pull-down sub-circuit, wherein
the pull-down control sub-circuit is electrically connected to the first reference voltage signal terminal, a third reference voltage signal terminal, the first node, a second node and the input signal terminal, and is configured to provide the first reference voltage signal from the first reference voltage signal terminal to the second node under the control of the input signal from the input signal terminal or the potential at the first node, or provide a third reference voltage signal from the third reference voltage signal terminal to the second node; and
the pull-down sub-circuit is electrically connected to the first node, the second node, the first reference voltage signal terminal, and the output signal terminal and is configured to provide the first reference voltage signal from the first reference voltage signal terminal to the first node or the output signal terminal under the control of a potential at the second node.

11. The gate driving circuit according to claim 10, wherein the pull-down control sub-circuit comprises a seventh switch transistor, an eighth switch transistor, and a ninth switch transistor, wherein
the seventh switch transistor has a gate and a first electrode both electrically connected to the third reference voltage signal terminal, and a second electrode electrically connected to the second node;
the eighth switch transistor has a gate electrically connected to the first node, a first electrode electrically connected to the first reference voltage signal terminal, and a second electrode electrically connected to the second node; and
the ninth switch transistor has a gate electrically connected to the input signal terminal, a first electrode electrically connected to the first reference voltage signal terminal, and a second electrode electrically connected to the second node.

12. The gate driving circuit according to claim 10, wherein the pull-down sub-circuit comprises a tenth switch transistor and a sixth switch transistor, wherein
the tenth switch transistor has a gate electrically connected to the second node, a first electrode electrically connected to the first reference voltage signal terminal and a second electrode electrically connected to the first node; and
the sixth switch transistor has a gate electrically connected to the second node, a first electrode electrically connected to the first reference voltage signal terminal and a second electrode electrically connected to the output signal terminal.

13. A display apparatus, comprising the gate driving circuit according to claim 1.

14. The gate driving circuit according to claim 5, wherein the shift registers each further comprise a node de-noising sub-circuit, wherein
the node de-noising sub-circuit is electrically connected to a frame start signal terminal, the first node and the first reference voltage signal terminal, and is configured to provide the first reference voltage signal from the first reference voltage signal terminal to the first node under the control of a signal from the frame start signal terminal.

15. The gate driving circuit according to claim 14, wherein the node de-noising sub-circuit comprises a fifth switch transistor, wherein
the fifth switch transistor has a gate electrically connected to the frame start signal terminal, a first electrode electrically connected to the first reference voltage signal terminal, and a second electrode electrically connected to the first node.

16. The gate driving circuit according to claim 5, wherein the shift registers each further comprise a pull-down control sub-circuit and a pull-down sub-circuit, wherein
the pull-down control sub-circuit is electrically connected to the first reference voltage signal terminal, a third reference voltage signal terminal, the first node, a second node and the input signal terminal, and is configured to provide the first reference voltage signal from the first reference voltage signal terminal to the second node under the control of the input signal from the input signal terminal or the potential at the first node or provide a third reference voltage signal from the third reference voltage signal terminal to the second node; and
the pull-down sub-circuit is electrically connected to the first node, the second node, the first reference voltage signal terminal, and the output signal terminal and is configured to provide the first reference voltage signal from the first reference voltage signal terminal to the first node or the output signal terminal under the control of a potential at the second node.

17. The gate driving circuit according to claim 16, wherein the pull-down control sub-circuit comprises a seventh switch transistor, an eighth switch transistor, and a ninth switch transistor, wherein
the seventh switch transistor has a gate and a first electrode both electrically connected to the third reference voltage signal terminal, and a second electrode electrically connected to the second node;
the eighth switch transistor has a gate electrically connected to the first node, a first electrode electrically connected to the first reference voltage signal terminal, and a second electrode electrically connected to the second node; and
the ninth switch transistor has a gate electrically connected to the input signal terminal, a first electrode electrically connected to the first reference voltage signal terminal, and a second electrode electrically connected to the second node.

18. The gate driving circuit according to claim 16, wherein the pull-down sub-circuit comprises a tenth switch transistor and a sixth switch transistor, wherein
the tenth switch transistor has a gate electrically connected to the second node, a first electrode electrically connected to the first reference voltage signal terminal and a second electrode electrically connected to the first node; and
the sixth switch transistor has a gate electrically connected to the second node, a first electrode electrically connected to the first reference voltage signal terminal and a second electrode electrically connected to the output signal terminal.

19. A display apparatus, comprising the gate driving circuit according to claim 2.

20. A display apparatus, comprising the gate driving circuit according to claim 5.
